(19) United States
(12) Patent Application Publication
(10) Pub. No.: US 2022/0020717 A1
(43) Pub. Date: Jan. 20, 2022

(54) STRENGTHENED WIRE-BOND

(71) Applicant: SEMICONDUCTOR COMPONENTS INDUSTRIES, LLC, Phoenix, AZ (US)

(72) Inventors: WuXing Xia, Suzhou (CN); Jingyan Liu, Suzhou (CN); Huaping Li, Suzhou (CN); ZhengXu Jia, Suzhou (CN)

(73) Assignee: SEMICONDUCTOR COMPONENTS INDUSTRIES, LLC, Phoenix, AZ (US)

(21) Appl. No.: 16/948,794

(22) Filed: Oct. 1, 2020

Related U.S. Application Data
(60) Provisional application No. 62/705,756, filed on Jul. 14, 2020.

(51) Int. Cl. H01L 23/00; H01L 23/495

(52) U.S. Cl. CPC H01L 24/48; H01L 23/4952; H01L 24/85; H01L 2224/48249; H01L 2224/85951; H01L 2224/48799; H01L 2224/48599; H01L 2224/48699; H01L 2224/85205; H01L 2224/48456

(57) ABSTRACT

An electrical circuit in a semiconductor package may include a wire connected at each end by a bond point formed using a wire-bonding machine. When a connection point (e.g., a die pad) has a very small dimension, the wire used for the circuit may be required to have a similarly small diameter. This small diameter can lead to a weak bond point, especially in bonds that include a heel portion. The heel portion is a transition region of the bond point that may have less strength (e.g., as measure by a pull-test) than other portions of the bond point and/or may be exposed to more forces than other portions of the bond point. Accordingly, a capping-bond point may be applied to the bond point to strengthen the bond point by clamping the heel portion and shielding it from forces that could cause cracks.

### CROSS-REFERENCE TO RELATED APPLICATIONS

This application claims the benefit of U.S. Provisional Patent Application No. 62/705,756, filed on Jul. 14, 2020, the entire contents of which is incorporated herein by reference.

### FIELD OF THE DISCLOSURE

The present disclosure relates to semiconductor device fabrication and more specifically to a type of wire-bond and a method for manufacture thereof.

### BACKGROUND

A wire bond may include a transition area (i.e., heel area) from a bonded portion of the wire to a loop portion the wire resulting from a deformation of the wire during a wire-bonding process. The heel area may be mechanically weaker than other areas of the wire, and as a result, an external force applied to the wire may likely split or break (i.e., crack) the wire in the heel area. Because a heel crack can reduce or eliminate conduction between bond points in a wire-bond connection, it is desirable to reduce or eliminate heel cracks in wire-bond connections.

### SUMMARY

In at least one aspect, the present disclosure generally describes a wire-bond. The wire-bond includes a bond point that bonds a first wire having a first diameter to a surface. The bond point includes a heel portion. The wire-bond also includes a capping-bond point that bonds a second wire having a second diameter to the bond point. The capping-bond point is configured to press the heel portion of the bond point against the surface.

In another aspect, the present disclosure generally describes a method for bonding a wire to a surface. The method includes pressing a first wire between the surface and a first wedge tool of a wire-bonding machine, and then applying energy (e.g., ultrasonic energy) to the first wire so that it forms a bond point with the surface. The bond point includes a heel portion. The method further includes pressing a second wire between the bond point and a second wedge tool of the wire-bonding machine, and applying energy (e.g., ultrasonic energy) to the second wire so that it forms a capping-bond point with the bond point. The second bond clamps the heel portion of the bond point

In another aspect, the present disclosure generally describes a package for a semiconductor device. The package includes a die that includes (at least one) die pad. The package further includes a lead frame that includes (at least one) lead post. The package further includes a first wire that connects the die pad and the lead post. The first wire is bonded to the lead post using a wire-bond that includes a bond point between the first wire and the lead post and a capping-bond point between a second wire and the bond point. The first wire in the bond point includes a heel portion and the capping-bond point is configured to press the heel portion against the lead post.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 illustrates a side cutaway view of a portion of a semiconductor package according to an implementation of the present disclosure.

FIG. 2 is a side view of a portion of a wire-bonding machine according to a possible implementation of the present disclosure.

FIG. 3 is a side-view of a bond point from FIG. 1 before a capping-bond point is applied to the bond point.

FIG. 4 is a side-view of the semiconductor package of FIG. 2 including a wire-bond machine positioned to create a capping-bond point on the bond point.

FIG. 5A is a side cutaway view of a bond point with the heel area highlighted.

FIG. 5B is a side cutaway view of the bond point of FIG. 5A after a capping-bond point has been applied and highlighting the heel area protected by the capping-bond point.

FIG. 5C illustrates a cross-sectional view of the wire-bond at a plane A-A′ shown in FIG. 5B.

FIG. 5D illustrates a cross-sectional view of the wire-bond at a plane B-B′ shown in FIG. 5B.

FIG. 6 is a top view image of a wire-bond according to an implementation of the present disclosure.

FIG. 7 is a top view image of a package having a wire-bond according to an implementation of the present disclosure on a lead frame.

FIG. 8A through 8M are diagrams that illustrate a method of making the wire bond according to an implementation of the present disclosure.

The components in the drawings are not necessarily to scale relative to each other. Like reference numerals designate corresponding parts throughout the several views.

### DETAILED DESCRIPTION

Packaging of an integrated circuit can include connecting a pad opening on a semiconductor die to a lead on a lead frame. Wire bonds can be used to connect various components within the package. The implementations described herein are directed to wire-bonds that are formed on a substrate (e.g., a lead frame, a semiconductor device, etc.) using a dual wire-bonding process where a first wire portion associated with a first wire is coupled at a bond point with the substrate and a second wire portion associated with a second wire (larger in diameter than the first wire) is coupled at a capping-bond point to (e.g., on top of) the first wire portion (and the substrate). The capping-bond point can entirely encapsulate at least some portions of the first wire portion so that the second wire portion is in contact with portions of the substrate around the first wire portion. The second wire portion can be a relatively short portion of wire (e.g., short in length as compared with the first wire) that is approximately the size of the bond point. The second wire portion is not coupled between electrical components.

This dual wire-bonding process, which can be referred to as a capped wire-bonding process or a dual-stage wire-bonding process, utilizes a capping-bond point applied to a bond point to strengthen the wire bond. The dual wire-bonding process can strengthen, for example, a heel area of the bond point that may be mechanically weaker than other areas of the wire. This strengthening can reduce and/or prevent splitting and/or breaking of the wire in the heel area in response to an external force applied to the wire. Further, the reduction in splitting and/or breaking of the wire can reduce or eliminate conduction issues between wire-bonds in a wire-bond connection.

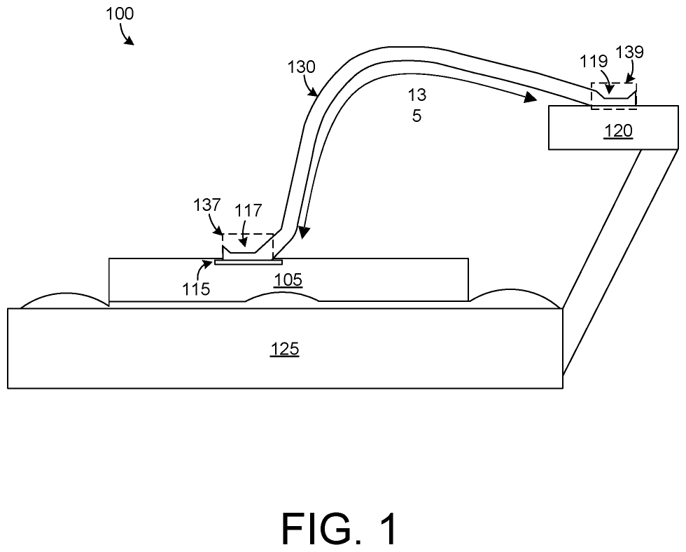

FIG. 1 illustrates a side cutaway view of portion of a semiconductor package 100 according to an implementation of the present disclosure. As shown, the package 100 may include a semiconductor die (i.e., die 105) affixed to a die-bed portion 125 of a lead frame. The die 105 can include at least one die pad opening (i.e., die pad 115) for electrically connecting the integrated circuit to the lead frame, and the lead frame can include at least one lead post 120, which can be electrically coupled to an external circuit. The pad 115 may be electrically coupled to the lead post 120 by a wire 130. The wire may be a metal, such as aluminum (Al), copper (Cu), or gold (Au) and have a small diameter (e.g., 2 mils) to facilitate a connection to a die pad 115 of a similar size. A wire-bond process can be used to form a wire loop (i.e., loop 135) that connects a first bond point 117 at the bond pad 115 to a second bond point 119 at the lead post 120.

As shown in FIG. 1, a first end of wire, fed from a wire supply, can be wire-bonded to the pad 115 using some combination of pressure, heat, and/or ultrasonic energy. The exact combination may depend on the type of wire-bond and the wire material. Using a type of wire-bonding known as ultrasonic wire-bonding, a fist bond point 117 can be formed by pressing the first end of the wire against the pad 115 and applying a ultrasonic energy (and in some cases heat) to a first end of the wire until the force, and ultrasonic energy (and in some cases heat) create an intermetallic bond between the first end of the wire 130 and the pad 115.

After forming the first bond point 117, wire fed from the wire supply may form a long (e.g., >100 mils) loop 135 between the pad 115 and the lead post 120. After forming the loop, a portion of the wire at the lead post can be-bonded to form a second bond point 119 on the lead post 120. In a possible implementation, the second bond point 119 may be formed using the same technique of applying pressure and ultrasonic energy that was used to form the first bond point 117. After forming the second bond point 119, the wire supply can be severed from the second bond point 119 so that what remains in the package 100 is wire 130 that is wire-bonded at one end to the pad 115 and wire-bonded at the opposite end to the lead post 120.

In a dual wire-bonding process, capping-bond points 137, 139 can be added to either, or both, the first bond point 117 and the second bond point 119. The capping-bond points 137, 139 are disposed on (e.g., mechanically disposed on) at least some portions of the wire 130 at the bond points 117, 119. The capping-bond point 137, 139 are disposed on (e.g., mechanically disposed on) using a wire-bonding process similar to that used for the bond points 117, 119, one difference being the use of a different wire (different from the wire 130 and not shown in FIG. 1) to form the capping-bond points 137, 139. In some implementations, the capping-bond points 137, 139 can be referred to as securing or cover bond points.

Each bond point 117, 119 may be one of a variety of types, such as a ball bond type (i.e., ball bond) or a wedge bond type (i.e., wedge bond). In a ball bond, a ball is formed on the first end of the wire (e.g., gold wire) before the wire is bonded to the pad. This approach allows the loop to be formed at a variety of angles with respect to the ball bond. In a wedge bond (i.e., heel stitch), the wire (e.g., aluminum wire) is bonded in a particular direction. Accordingly, the loop and the wedge bond are oriented in the same general direction. A wire-bond connection between the two bond points 117, 119 may include ball bond on either end (i.e., ball-ball bonding), wedge bonds on either end (i.e., wedge-wedge bonding), or a ball bond on one end and a wedge bond on the other end (i.e., ball-wedge bonding). While the disclosed techniques can work for a variety of bond point types, a bond point (i.e., wire-bond) created using a wedge, ultrasonic wire-bonding process will be described in detail in the disclosure.

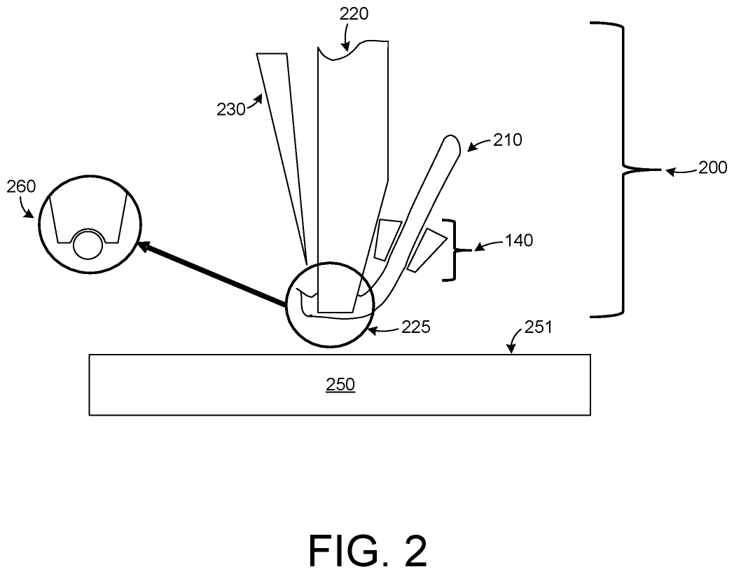

Bond points 117, 119, such as shown in FIG. 1, may be created using a wire-bonding machine. FIG. 2 illustrates a side view of a portion of a wire-bonding machine 200 that can be used in connection with the dual wire-bonding process implementations described herein. The wire-bonding machine 200 includes a wedge tool 220 that positions the wire 210 from a wire supply (not shown) at a tip 225. A front view of the tip 225 is shown in the inset 260. A shown, the tip of the wedge tool can include an indention (e.g., groove) configured to receive the wire 210. An interior surface of the indentation may be one of variety of shapes, such as round triangular, and trapezoidal.

To bond the wire 210 to a surface 251 of a substrate 250 (e.g., a lead, a pad, etc.), the wedge tool 220 can be lowered towards the surface 251 so that the wire 210 pressed with a downward force between the surface 251 and the interior surface of the indentation of the wedge tool 220 at the tip 225. Ultrasonic energy can then be coupled to the wedge tool 220 to that the combined pressure and ultrasonic energy soften the wire is deformed and an intermetallic bond is created between the substrate and the wire.

The wire-bonding machine 200 may further include a blade 230 that can be lowered to cut a bond point from the wire supply. The wire-bonding machine 200 may further include a clamp 140 that can grip the wire supply to prevent wire from being fed from the wire supply, such as for example, when separating the bond point from the wire supply.

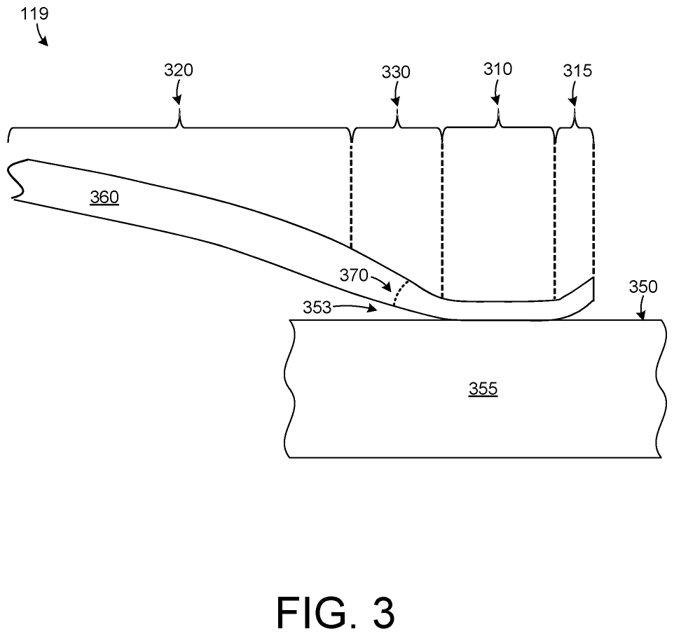

FIG. 3 is a side-view of the second bond point 119 of FIG. 1 before a capping-bond point 139 is applied. As shown, the combined pressure and ultrasonic energy deforms the wire, thereby forming distinct portions in the bond point.

A first portion of a bond point is a bond portion 310. In the bond portion, the wire, having been flattened by the pressure of the wedge tool, can be thinner than in other portions. In the bond portion 310 an intermetallic bond exists between the wire 360 and a surface 350 of the substrate 355. Accordingly, in the bond portion 310 the wire 360 is substantially flush with the surface 350 of the substrate 355. In some cases, a tail portion 315 exists as a result of cutting the wire after bonding. The tail portion 315 is typically small (i.e., relative to the bond portion 310) and does not affect an electrical connection between bond points.

A second portion of a bond point is a wire portion 320. The wire portion 320 is far enough away from the bond portion 310 that it does not experience a deformation caused by the wire-bond process. In the wire portion 320, the wire may have a uniform diameter. In the wire portion 320, the wire may follow a loop profile that is largely set by the movement of the wire bonding machine.

A third portion of a bond point is a heel portion 330. In the heel portion 330 the wire transitions from the flattened condition of the bond portion 310 to the undeformed condition of the wire portion 320. Accordingly, in the heel portion 330 the wire 360 may have a diameter that changes as it progresses from the bond portion 310 to the wire portion 320.

The heel portion of a bond point may have one or more mechanical properties of the wire 360 that have been affected by the pressure and the heating applied during the wire-bonding process. As a result, the heel portion 330 may be mechanically weaker than the wire portion 320 or the bond portion 310.

Without the benefit of the dual wire-bonding process and a capping-bond point, the heel portion 330 of a bond point may have a portion of the wire 360 that is not bonded to the surface 350 of the substrate 355. Accordingly, a gap 353 may exist between the wire 360 and the surface 350 of the substrate 355. The gap may increase in size as it progresses from the bond portion 310 to the wire portion 320. This gap 353 can allow forces on the wire that can lead to a crack in the wire, known as a heel crack 370. Because a heel crack can reduce or eliminate conduction between the pad and the lead, it is desirable to reduce or eliminate heel cracks in wire-bond connections.

After wire-bonding, a package may be encapsulated to prevent damage and corrosion. During encapsulation, an electronic mold compound (e.g., a polymer) in liquid form can be added to the package and then hardened. The electronic mold compound ideally surrounds the bond point 119 uniformly; however, without the benefit of the dual wire-bonding process and a capping-bond point, the gap 353 may cause non-uniformities (e.g., a voids) in the encapsulation.

Without the benefit of the dual wire-bonding process and a capping-bond point, heel cracks can result from the non-uniformities in the encapsulation. For example, a non-uniform encapsulation can lead to forces that can crack the wire during encapsulation as the electronic mold compound is harden. A non-uniform encapsulation can also lead to forces that can crack the wire after encapsulation, when the package experiences different environments (e.g., at different temperatures). The non-uniformities in the encapsulation can also trap moisture, which can create forces (e.g., due to a phase change) resulting in a heel crack.

Heel cracks can also result from workmanship. For example, variations in the pressure and ultrasonic energy can lead to heel portions with various mechanical strengths. Additionally, forces from mechanical vibration and/or shock during fabrication (e.g., before encapsulation) can lead to a heel crack.

A heel crack may be a partial crack that affects a conductivity of the electrical connection (e.g., increases a resistance) between bond points. Alternatively, a heel crack can be a complete crack (i.e., break) that severs an electrical connection between bond points. A heel crack can lower a strength of a bond point.

A test that used to measure the strength of a bond point is a pull-test. In a pull-test, the wire loop is pulled until the wire breaks. For the bond points without the dual wire-bonding process, the breakage is typically in the heel portion 330, which can be the weakest point of the wire.

The present disclosure describes a wire-bond that is strengthened through the use of multiple, overlapping bond point. In a strengthened bond point a heel portion can be shielded from forces that would otherwise cause a crack. As a result, a pull-test of a strengthened wire bond results in a larger force (e.g., up to 40%) to break the wire than observed in a pull-test of a wire bond without strengthening. One reason for the increase in the pull-test force is that the break occurs in the wire portion and not the heel portion.

The bond point described thus far may include wire of a relatively small wire diameter (e.g., 2 mil). The selection of the wire diameter may be based on a dimension of a (e.g., 2 mil) die pad. In other words, a relatively small die pad may necessitate a bond point including a similarly sized wire diameter. The resulting bond point may be weak (e.g., based on a pull-test) because the relatively small diameter wire may have an even smaller dimension in a heel portion (i.e., neck area), which is prone to cracking.

To strengthen a bond point (i.e., first bond point, small bond point), a capping-bond point (i.e., second bond point, large bond point) may be coupled (e.g., bonded, fixedly coupled) on the first bond point. The capping-bond point can include a second wire having a second wire diameter (e.g., >8 mils) that is large relative to a first wire diameter of the first wire in the bond point. For example, the diameter of the second wire may be at least four times (4×) greater than a diameter of the first wire. More specifically, a diameter of the first wire may be less than or equal to two mils (d₁≤2 mils) while a diameter of the second wire may be greater than or equal eight mils and less than or equal to twenty mils (8 mils≤d₂≤20 mils). The capping-bond point may be a second bond type (e.g., wedge bond) that is the same as the first bond type of the bond point. The capping-bond point can include a second bond portion that covers at least the first heel portion of the bond point. In some implementations, the capping-bond point includes a bond portion that covers both the first bond portion and the first heel portion of the bond point. The capping-bond point can include a second wire of a second conducting material, such as aluminum, copper, or gold. The second wire material of the capping-bond point and the first wire material of the first wire-bond can be different materials. Alternatively, the first wire and the second may be the same material.

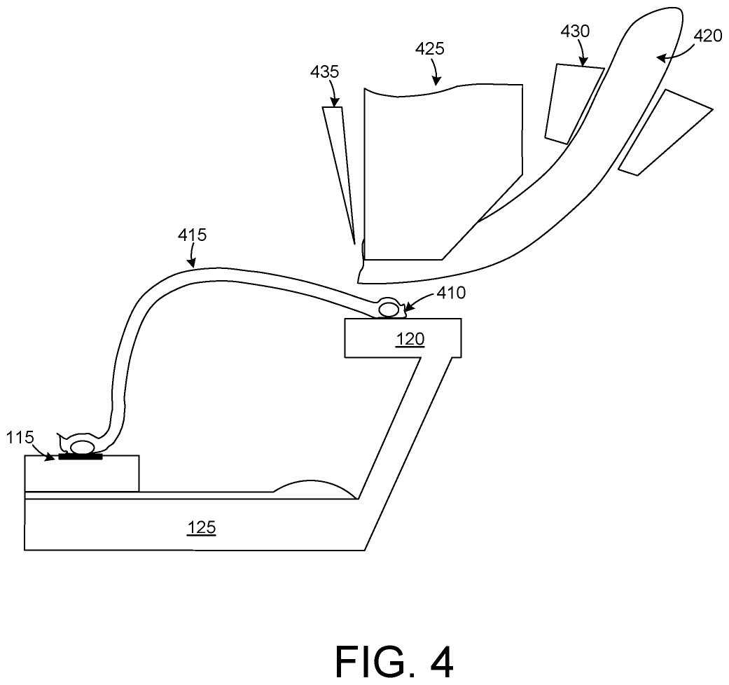

FIG. 4 is a side view of the semiconductor package of FIG. 2 including a wire-bonding machine positioned to create the capping-bond point to strengthen the bond point 410 on the lead post 120. The wire bonding machine may be as described in FIG. 2 but can include a wire 420 of a larger diameter than the wire 415 of the lead post bond point 410 (i.e., smaller bond point). Accordingly, the wire-bonding machine may also be fit with a wedge tool 425, a clamp 430, and/or a blade 435 to accommodate the larger wire diameter.

The same wire bonding machine may be used to form the smaller (i.e., connecting) bond point and the larger (i.e., strengthening) capping-bond point, but the wire-bonding machine may be configured differently for each. Using the same wire-bonding machine to produce the connecting bond point and the strengthening capping-bond point may advantageously simplify a process to create a wire bond that resists heel cracks. Using the same wire-bonding machine may provide a choice of a plurality of wire diameters for strengthening the connecting bond point. For example, a wire-bonding machine that can create a 2mils connecting bond point (i.e., smaller bond point) may also be configured to create an 8 mils, 10 mils, 15 mils, or 20 mils strengthening capping-bond point (i.e., larger bond point).

As shown in FIG. 4, to form a larger capping-bond point to strengthen the lead post bond point 410 (i.e., smaller bond point), the wire bonding machine can be positioned over the smaller bond point and lowered to press the wire 420 between the wedge tool 425 and an area including the lead post 120 and the lead post bond point 410. Ultrasonic energy may then be applied to the wire through the wedge tool 425 so that the wire 420 softens and conforms to the lead post bond point. The ultrasonic energy may then be removed, and an intermetallic bond may be formed between the wire and the lead post 120 and/or lead post bond point 410. The wire supply can be clamped using the clamp 430 and the blade 435 may be lower to separate the wire supply from the strengthening capping-bond point. What remains is a larger capping-bond point that covers the smaller bond point. The larger capping-bond point may include a bond portion between a first tail portion and a second tail portion. In other words, the strengthening bond point does not include a wire portion or a heel portion.

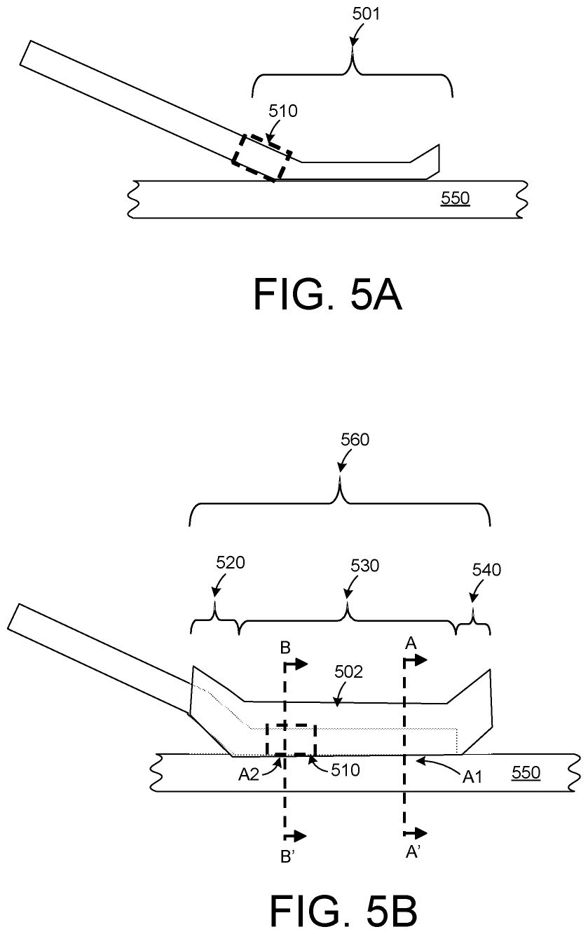

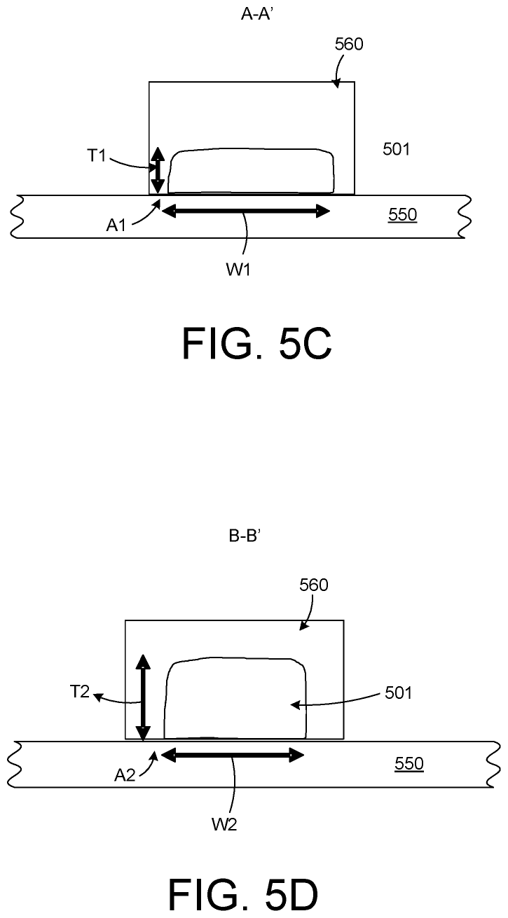

FIG. 5A illustrates a side view of a smaller bond point 501 that includes a relatively weak heel portion 510 before a capping-bond point 560 is applied (as shown in FIG. 5B). FIG. 5B illustrates a side view of the smaller bond point 501 covered by a capping-bond point 560 to form a dual wire-bond (i.e., strengthen wire-bond, wire-bond). The capping-bond point 560 includes a bond portion 530 between a first tail portion 520 and a second tail portion 540. The bond portion 530 of the capping-bond point 560 may completely cover the heel portion 510 of the smaller bond point 501. The heel portion 510 of the smaller bond point 501 may be pressed (i.e., clamped) and/or bonded to the surface by the capping-bond point 560. As a result, the weakest portion of the smaller bond point 501 is shielded from experiencing forces that could cause a heel crack, and the overall wire-bond is strengthened. In a pull test, a breaking force of the strengthened wire-bond can be larger (e.g., 40% larger) than in a wire-bond without strengthening by the capping-bond point 560. Additionally, in a pull-test of a strengthened wire bond, breakage may be located in the wire loop instead of the heel portion.

In this implementation, the smaller bond point 501 can be coupled at interface area Al to the substrate 550 via a first wire-bond process and can be further pressed (and coupled) against the substrate 550 when the capping-bond point 560 is applied via a second wire-bond process. During the second wire-bond process at least a portion of the capping-bond point 560 is coupled to the substrate 550. Accordingly, the interface area Al can include a portion of a first wire (associated with the smaller bond point 501) contacted via a first wire-bond process to the substrate 550 and a second wire (associated with the capping-bond point 560) contacted via a second wire-bond process to the substrate 550.

In this implementation, the heel portion 510 can be coupled at interface area A2 to the substrate 550 via the second wire-bond process when the capping-bond point 560 is applied via the second wire-bond process. The interface area A2 is disposed between the interface area Al and the wire (to the left as shown in FIG. 5B). Accordingly, the interface area A2 can include a portion of a first wire (associated with the heel portion 510 smaller bond point 501) and a second wire (associated with the capping-bond point 560) both contacted via a second wire-bond process to the substrate 550.

FIGS. 5C and 5D illustrate cross-sectional views of the wire bond shown in FIG. 5B at interface areas A1 and A2, respectively. The wire bond includes a cross section of the smaller bond point 501 and a cross section of the capping-bond point 560. In both figures, the capping-bond point 560 entirely encapsulates (e.g., surrounds) the cross section of the smaller bond point 501. The capping-bond point 560 has portions coupled (e.g., fixedly coupled) to substrate 550 on the left and right side of the smaller bond point 501. The capping-bond point 560 fixedly couples (e.g., maintains contact between) the smaller bond point 501 to the substrate 550. Said differently, the capping-bond point 560 clamps or holds the smaller bond point 501 to the substrate 550.

As shown in FIG. 5C, because the smaller bond point 501 is coupled to the substrate 550 directly via two wire-bond processes (i.e., a first wire-bond process and is further pressed via a second wire-bond process) a thickness T1 can be smaller than a thickness T2. The thickness T2 is greater than thickness T1 because the heel portion 510 is coupled at interface area A2 to the substrate 550 via only the second wire-bond process when the capping-bond point 560 is applied via the second wire-bond process. For the same reasons, the width W1 is greater than the width W2. In other words, the smaller bond point 501 at interface area Al has a relatively small thickness T1 and relatively large width W1 because the smaller bond point 501 is coupled to the substrate 550 via a first wire-bond process and is further pressed (and coupled) against the substrate 550 when the capping-bond point 560 is applied via a second wire-bond process. Also, the thickness T2 is greater than thickness T1 and the width W2 is smaller than the width W1 because the heel portion 510 is coupled at interface area A2 to the substrate 550 via only the second wire-bond process when the capping-bond point 560 is applied via the second wire-bond process.

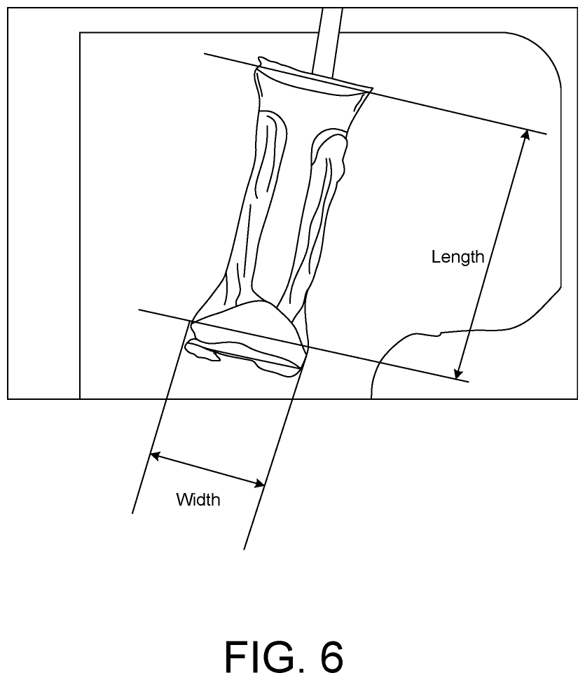

FIG. 6 is a top microscopic view of a strengthened wire-bond showing the larger wire bond having a length and a width that completely covers the smaller bond point. As shown the larger capping-bond point may include beveled surfaces that result from cutting and pressing operations during wire-bonding.

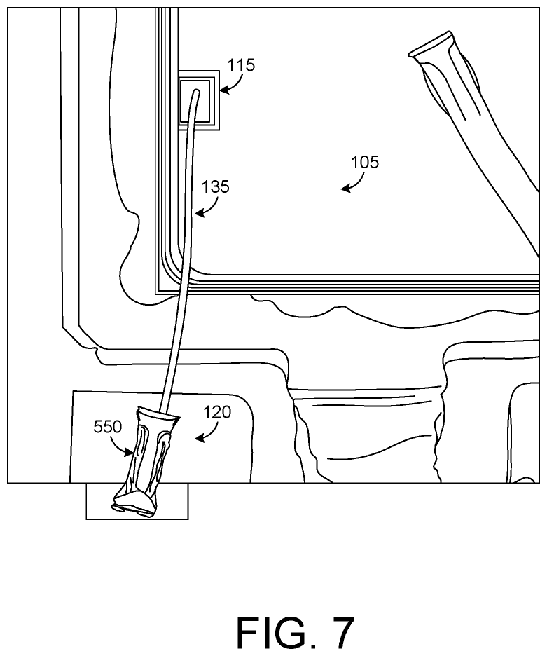

FIG. 7 is a top microscopic view of a package prior to encapsulation. The package includes a die 105 having a die pad 115 that is connected by a wire loop 135 to a lead post 120. The connection at the lead post is a strengthened wire bond. As shown, a larger capping-bond point covers a smaller bond point so that only the wire loop is exposed to forces and so that the gap in the heel portion of the smaller bond is covered.

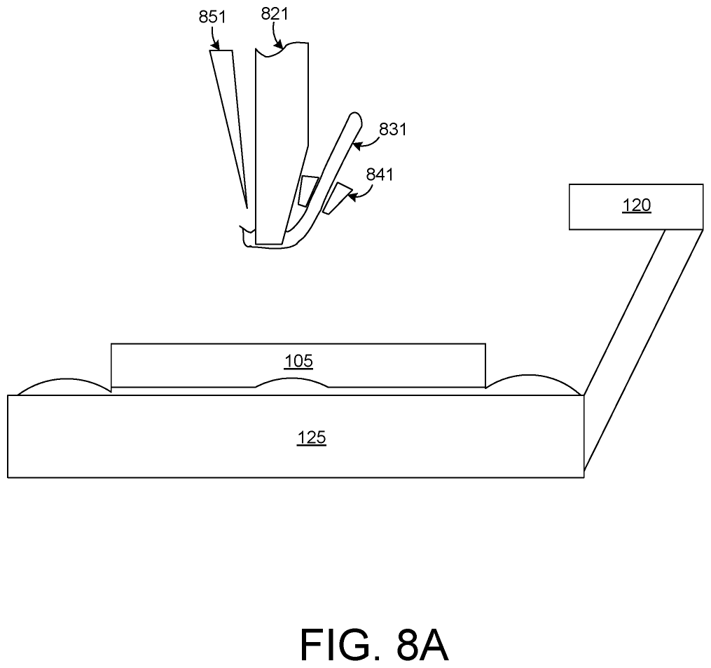

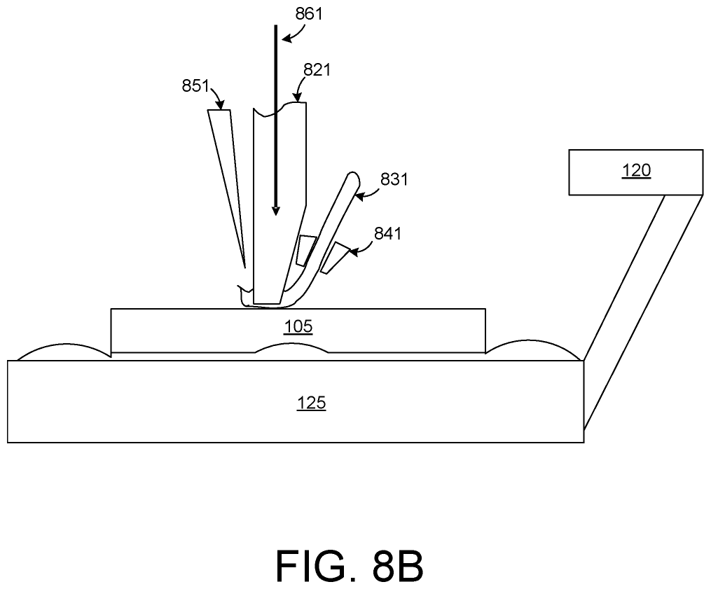

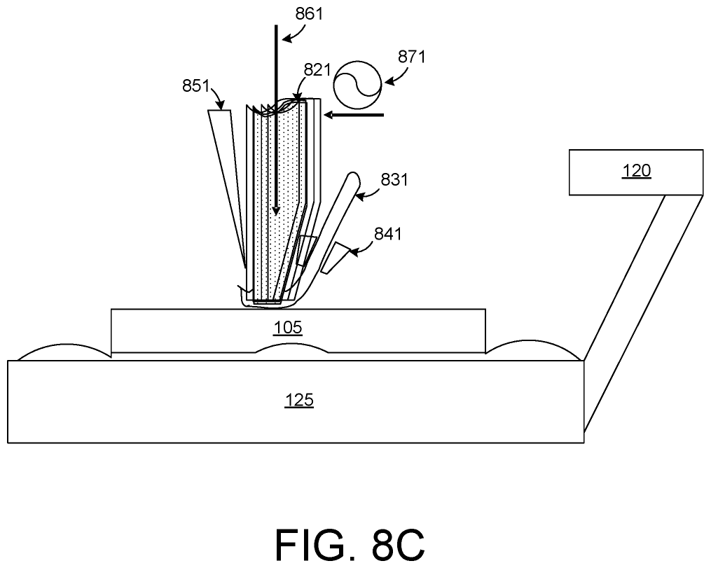

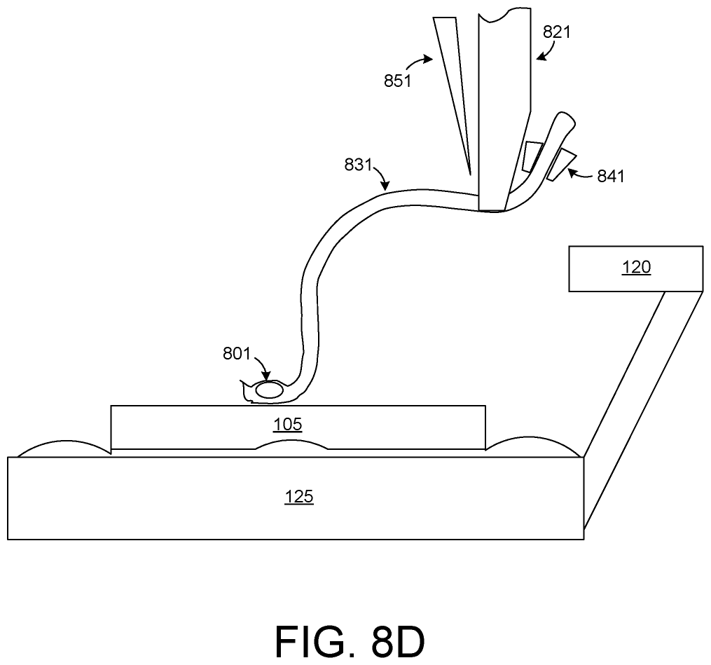

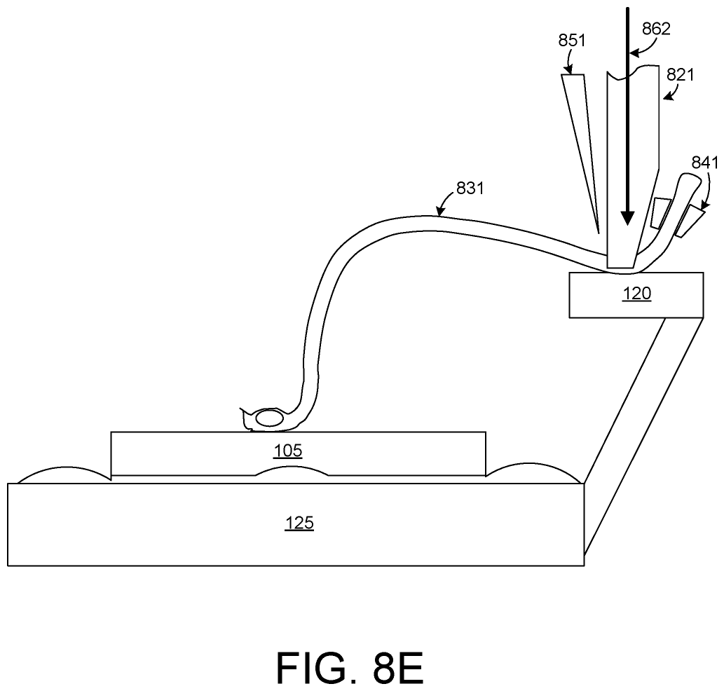

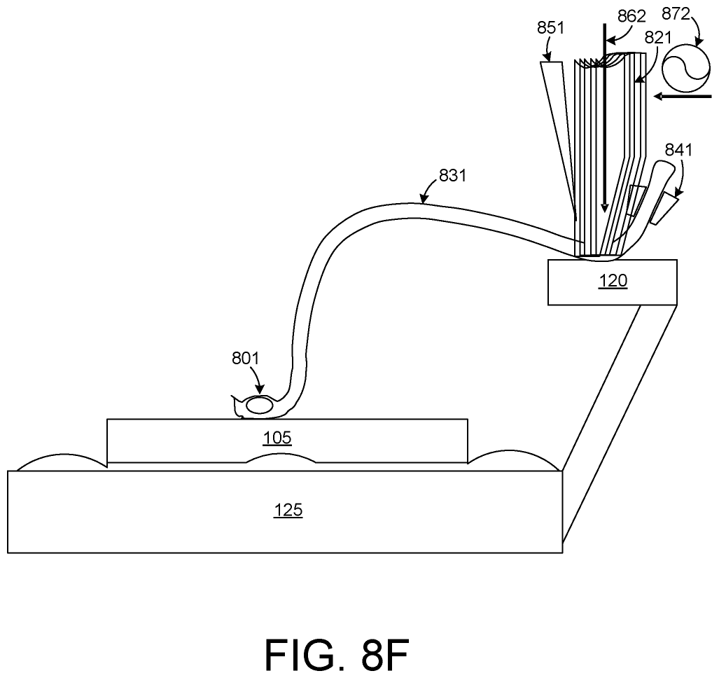

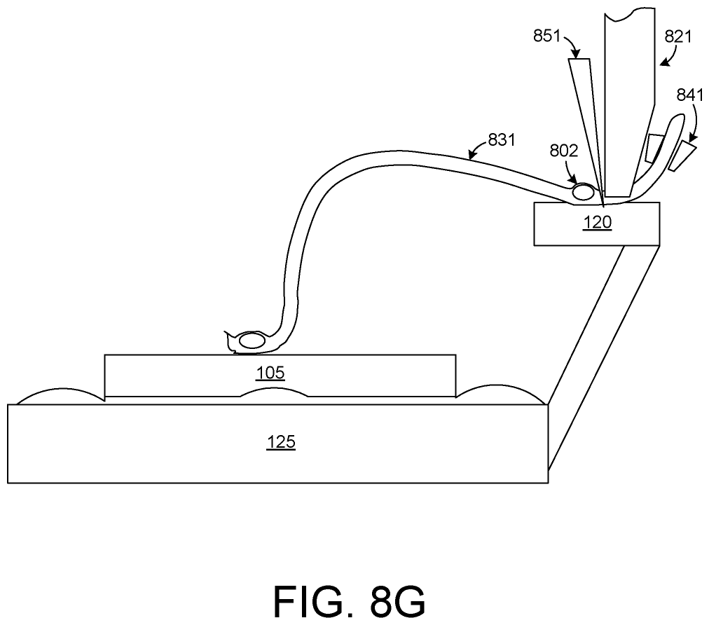

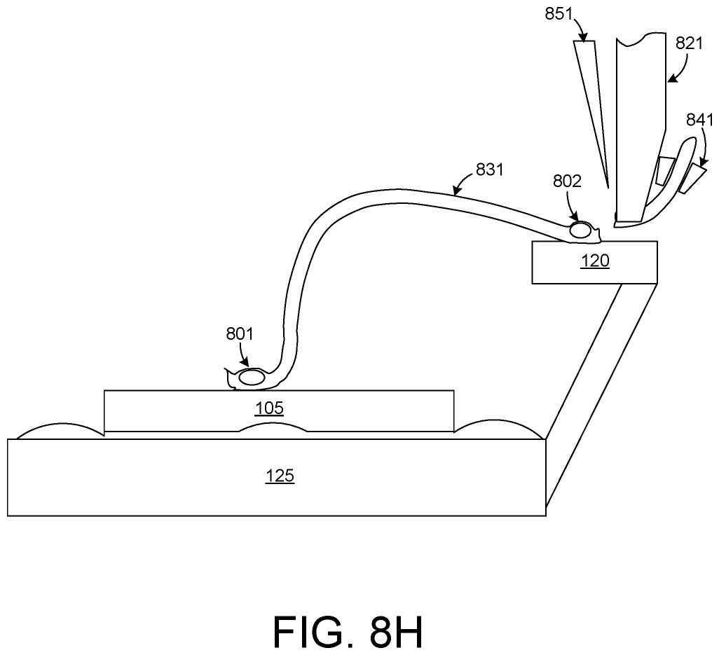

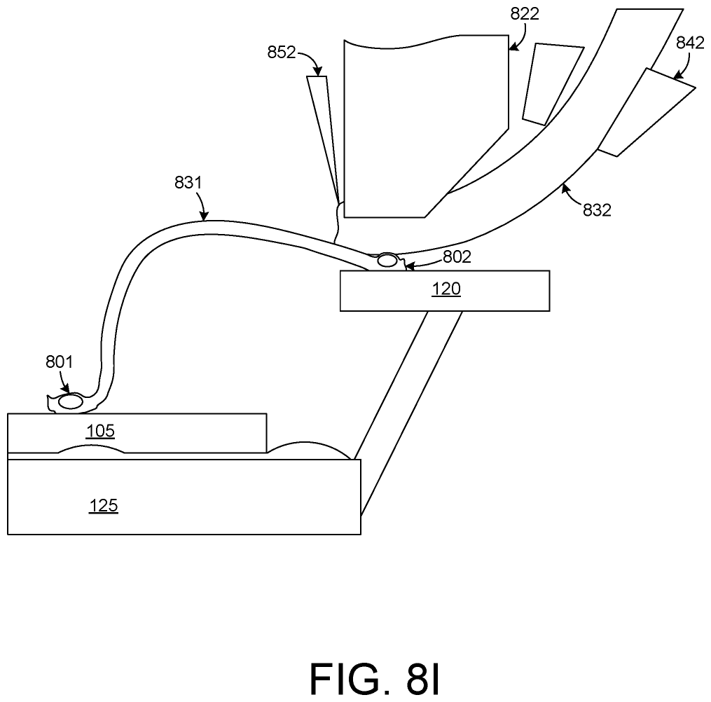

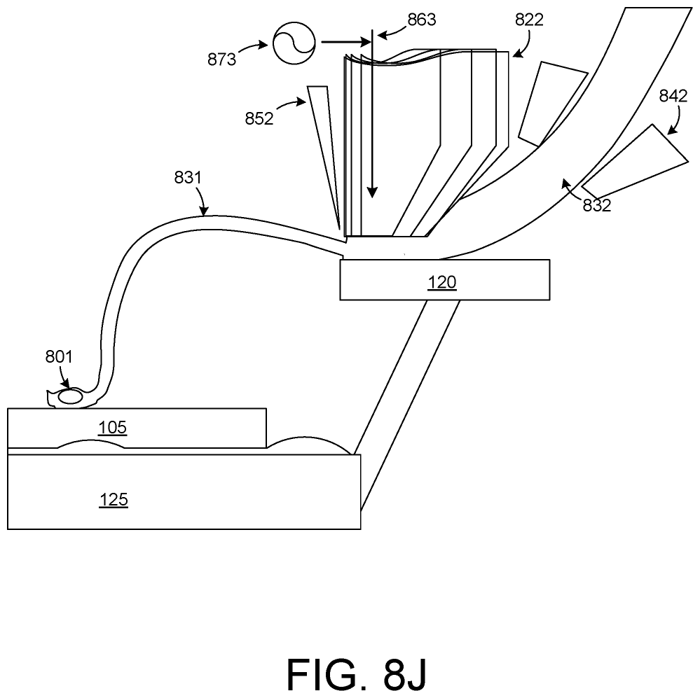

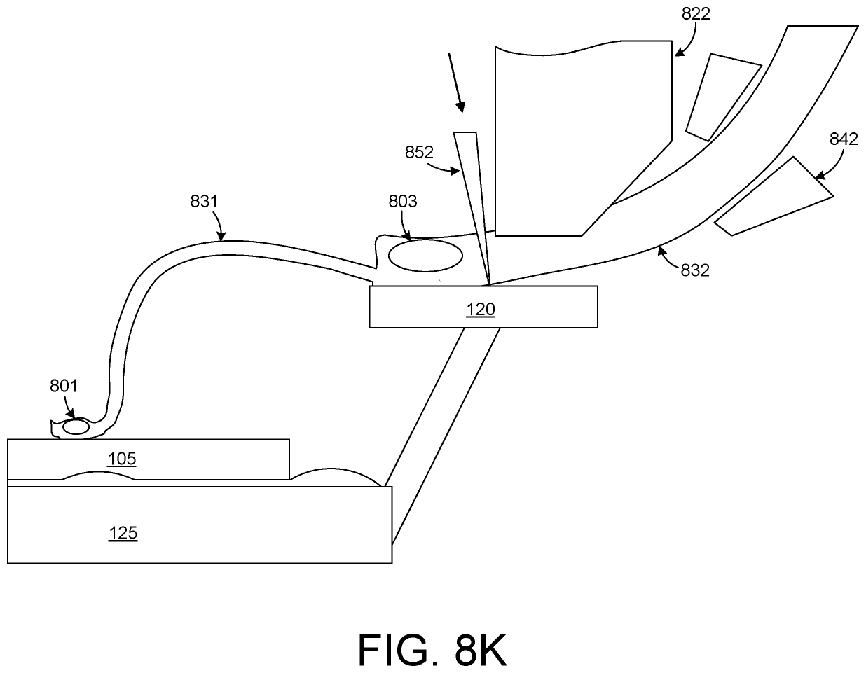

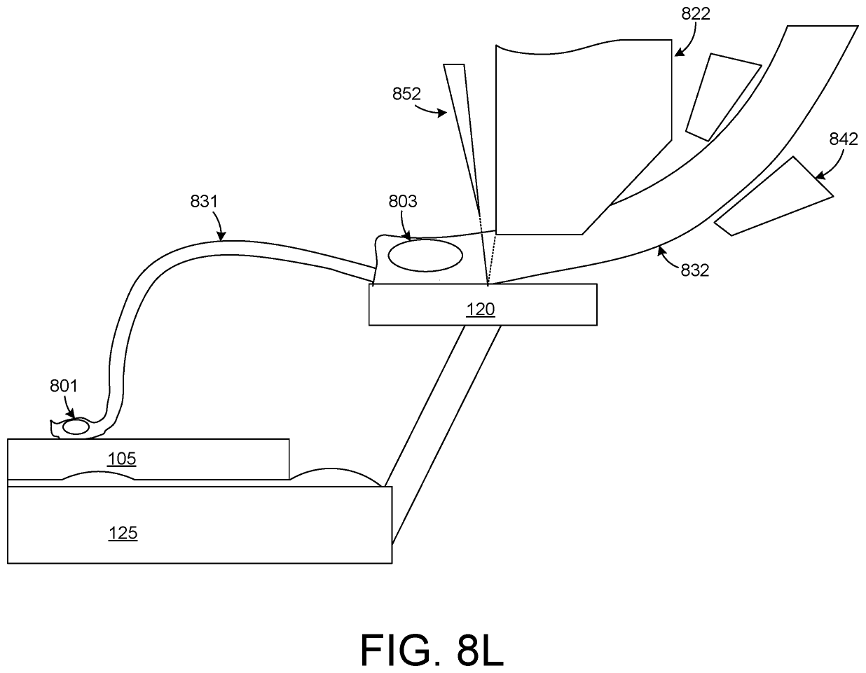

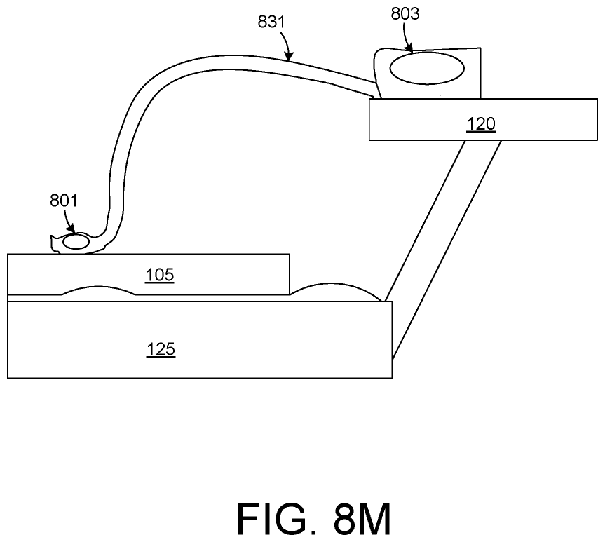

FIG. 8A through 8M are diagrams that illustrate a method of making the wire-bond. The method includes configuring a wire-bonding machine in a first configuration to form a first bond point in a package. The package can include a die 105 mounted in a die bed portion 125 of a lead frame and a lead post 120.

FIG. 8A illustrates the package and a portion of the wire-bonding machine in the first configuration. In the first configuration, the wire-bonding machine can include first wedge tool 821, a first wire 831, a first clamp 841, and a first blade 851. To form the first bond point between the first wire 831 and the die 105, the wire-bonding machine is lowered to a top surface of the die 105.

As shown in FIG. 8B, a first force 861 is applied to the wire-bonding machine in order to press the wire 831 between the first wedge tool 821 and the die 105. As shown in FIG. 8C, while the first force 861 is applied, a first ultrasonic energy 871 is applied to the first wire 831 through the first wedge tool 821. The first force 861 and the first ultrasonic energy 871 are applied for a first bond duration to form a first bond point 801. The first bond point 801 anchors the first wire 831.

As shown in FIG. 8D, the wire bonding machine can then be lifted and moved to the lead post 120 to form a second bond point. As the wire bonding machine is moved, the first wire 831 is fed from a supply to form a wire loop.

As, shown in FIG. 8E, a second force 862 is applied to the wire-bonding machine in order to press the first wedge tool first wire 831 between the lead post 120 and the first wedge tool 821.

As shown in FIG. 8F, while the second force 862 is applied, a second ultrasonic energy 872 is applied to the first wire 831 through the first wedge tool 821. The second force 862 and the second ultrasonic energy 872 are applied for a second bond duration to bond the first wire 831 to the lead post 120.

As shown in FIG. 8G, after a second bond point 802 is formed, the first blade 851 can be positioned and lowered to cut the first wire 831 at a side of the second bond point 802 opposite to the wire loop.

As shown in FIG. 8H, the first clamp 841 may be closed on the wire supply and the wire-bonding machine may then be lifted to separate the wire-bond connection between the first bond point 801 and the second bond point 802 from the wire-bonding machine.

The method further includes configuring the wire-bonding machine in a second configuration to form a capping-bond point to strengthen the second bond point. FIG. 81 illustrates a portion of the wire-bonding machine in the second configuration. In the second configuration, the wire-bonding machine can include a second wedge tool 822, a second wire 832, a second clamp 842, and a second blade 852. To form the capping bond to strengthen the second bond point 802, the wire-bonding machined in lowered over the second bond point 802.

As shown in FIG. 8J, a third force 863 is applied to the wire-bonding machine in order to press the second wire 832 between the second wedge tool 822 and the second bond point 802. While the third force 863 is applied, a third ultrasonic energy 873 is applied to the second wire 832 for a third bond duration to form a capping-bond point 803.

As shown in FIG. 8K, the wire bonding machine can then be lifted and moved to position the second blade 852. The second blade 852 can then be lowered (i.e., see arrow) to cut the second wire 832 at a side of the capping-bond point 803 opposite the first wire 831 (i.e., opposite to the wire loop).

As shown in FIG. 8L, the second clamp 842 may then be closed on the wire supply and the wire-bonding machine in the second configuration may be lifted to separate the capping-bond point 803 from the wire-bonding machine.

As shown in FIG. 8M, the capping-bond point 803 covers the second bond point 802 in the wire-bond connection. As a result, the wire bond connection is stronger. For example, a pull test on the first wire 831 with the capping-bond point 803 will yield a higher force required for breakage than a wire-bond connection without the capping-bond point 803.

In the specification and/or figures, typical embodiments have been disclosed. The present disclosure is not limited to such exemplary embodiments. The use of the term “and/or” includes any and all combinations of one or more of the associated listed items. The figures are schematic representations and so are not necessarily drawn to scale. Unless otherwise noted, specific terms have been used in a generic and descriptive sense and not for purposes of limitation.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. A wire-bond, comprising:
a bond point that bonds a first wire having a first diameter to a surface, the bond point including a heel portion; and
a capping-bond point that bonds a second wire having a second diameter to the bond point, the capping-bond point configured to fixedly couple the heel portion of the bond point against the surface.

2. The wire-bond according to claim 1, wherein:
the first wire and the second wire are different materials.

3. The wire-bond according to claim 2, wherein:
the first wire is copper or gold and the second wire is aluminum.

4. The wire-bond according to claim 1, wherein:
the bond point is formed using a wire-bonding machine in a first configuration and the capping-bond point is formed us the wire-bonding machine in a second configuration.

5. The wire-bond according to claim 1, wherein:
the second diameter is at least four times greater than the first diameter.

6. The wire-bond according to claim 1, wherein:
the capping-bond point covers the heel portion, a bond portion, and a wire portion of the bond point.

7. The wire-bond according to claim 1, wherein:
the first wire and the second wire are both aluminum, copper, or gold.

8. The wire-bond according to claim 1, wherein:
the first diameter corresponds to a dimension of a die pad on a die.

9. The wire-bond according to claim 8, wherein:
the first diameter is 2mils or less.

10. The wire-bond according to claim 9, wherein:
the second diameter is greater than or equal to 8mils and less than or equal to 20mils.

11. The wire-bond according to claim 1, wherein:
the bond point is a wedge bond type and the capping-bond point is the wedge bond type.

12. The wire-bond according to claim 1, wherein:
a breaking force resulting from a pull test of the wire-bond is increased by the capping-bond point.

13. A method for bonding a wire to a surface, the method comprising:
pressing a first wire between the surface and a first wedge tool of a wire-bonding machine;
applying energy to the first wire so that the energy forms a bond point with the surface, the bond point including a heel portion;
pressing a second wire between the bond point and a second wedge tool of the wire-bonding machine; and
applying energy to the second wire so that the energy forms a capping-bond point with the bond point, the capping-bond point clamping the heel portion of the bond point to the surface.

14. The method for bonding a wire to a surface according to claim 13, wherein:
the energy is ultrasonic energy.

15. The method for bonding a wire to a surface according to claim 13, wherein:
the capping-bond point clamps the heel portion of the bond point to prevent the heel portion from experiencing forces that cause heel cracks.

16. The method for bonding a wire to a surface according to claim 13, wherein:
clamping the heel portion of the bond point reduces a gap between the heel portion and the surface.

17. The method for bonding a wire to a surface according to claim 13, wherein:
a diameter of the second wire is at least four times larger than a diameter of the first wire.

18. A package for a semiconductor device, the package comprising:
a die including a die pad;
a lead frame including a lead post; and
a first wire connecting the die pad and the lead post, the first wire bonded to the lead post using a wire-bond that includes:
a bond point that bonds the first wire to the lead post, the bond point including a heel portion; and
a capping-bond point that bonds a second wire to the bond point, the capping-bond point configured to press the heel portion against the lead post.

19. The package for a semiconductor device according to claim 18, wherein:
the capping-bond point presses the heel portion against the lead post to point to strengthen the bond point.

20. The package for a semiconductor device according to claim 18, wherein a first diameter of the first wire is smaller than a second diameter of a second wire.
